(19) United States
(12) Patent Application Publication
(10) Pub. No.: US 2023/0154530 A1
(43) Pub. Date: May 18, 2023

(54) ELECTRONIC DEVICE AND ELECTRONIC DEVICE CONTROL METHOD

(71) Applicant: VMEMORY CORP., Giheung-gu Yongin-si Gyeonggi-do (KR)

(72) Inventors: Jong Hwa SON, Giheung-gu Yongin-si Gyeonggi-do (KR); Jong Yeog SON, Hwaseong-si Gyeonggi-do (KR)

(21) Appl. No.: 17/919,937

(22) PCT Filed: Apr. 22, 2021
(86) PCT No.: PCT/KR2021/005117

§ 371 Date: Oct. 19, 2022

(30) Foreign Application Priority Data
Apr. 22, 2020 (KR) 10-2020-0048854

(51) Int. Cl. G11C 13/00

(52) U.S. Cl. CPC G11C 13/0021

(57) ABSTRACT

Provided is an electronic device including a first electrode part including a conductive material, a second electrode part spaced apart from the first electrode part and including a conductive material, an active layer disposed between the first electrode part and the second electrode part, including a spontaneously polarizable material, and formed to optionally have a first mode having a first electrical resistance and a second mode having a value smaller than the first electrical resistance, and an electric field controller connected to the first electrode part and the second electrode part to apply an electric field.

### TECHNICAL FIELD

The present disclosure relates to an electronic device and a method for controlling the same.

### BACKGROUND ART

With the development of technology and increasing interest in people's convenience in life, attempts to develop various electronic products are increasing.

In addition, smaller and more integrated these electronic products are being developed, and the range of places where these electronic products is being wider.

Such electronic products include various electronic devices, for example, CPUs, memories, and other various electronic devices. These electronic devices may include various types of electrical circuits.

Electronic devices are used in products in various fields, such as home sensor devices for IoT, bio-electronic devices for ergonomics, as well as computers and smartphones.

Meanwhile, in response of the increase in the recent speed of technological development and the rapid improvement of the living standards of users, the use and application fields of these electric devices are getting wider, and the demand thereof is also increasing accordingly.

However, there is a limit in implementing and controlling an electronic circuit that is easily and quickly applied to various commonly used electrical devices, according to this trend.

Meanwhile, memory devices, particularly, nonvolatile memory devices, are widely used as information storage and/or processing devices of various electronic devices, such as cameras and communication devices, as well as computers.

These memory devices are being developed particularly in terms of lifespan and speed. Most issues to be addressed are associated with memory lifespan and speed. However, there is a limit to realizing memory devices with improved memory lifespan and speed.

### DETAILED DESCRIPTION OF THE INVENTION

### Technical Problem

The present disclosure can provide an electronic device that can be easily applied to various uses and a method of controlling the same.

### Technical Solution to Problem

An embodiment of the present disclosure provides an electronic device including: a first electrode part including a conductive material; a second electrode part spaced apart from the first electrode part and including a conductive material; an active layer disposed between the first electrode part and the second electrode part, including a spontaneously polarizable material, and formed to optionally have a first mode having a first electrical resistance and a second mode having a value smaller than the first electrical resistance; and an electric field controller connected to the first electrode part and the second electrode part to apply an electric field.

In an embodiment, the electronic device further includes a first connection electrode and a second connection electrode formed to be spaced apart from the first electrode part and the second electrode part on the active layer.

An embodiment of the present disclosure provides a method of controlling an electronic device including: a first electrode part including a conductive material; a second electrode part spaced apart from the first electrode part and including a conductive material; an active layer disposed between the first electrode part and the second electrode part, including a spontaneously polarizable material, and formed to optionally have a first mode having a first electrical resistance and a second mode having a value smaller than the first electrical resistance; and an electric field controller connected to the first electrode part and the second electrode part to apply an electric field, the method including optionally controlling a resistance value of the electronic device by controlling the selection of the first mode and the second mode of the active layer.

In the present embodiment, a first connection electrode and a second connection electrode formed to be spaced apart from the first electrode part and the second electrode part on the active layer, are included and the flow of current between the first connection electrode and the second connection electrode is controlled.

Other aspects, features and advantages other than those described above will become apparent from the following drawings, claims, and detailed description of the disclosure.

### Advantageous Effects of Disclosure

An electronic device and a method of controlling the same according to the present disclosure provides improved electrical properties and manufacturing properties, and can be easily applied to various uses.

### BRIEF DESCRIPTION OF DRAWINGS

FIG. 1 is a schematic diagram illustrating an electronic device according to an embodiment of the present disclosure.

FIG. 2 is a diagram illustrating an optional embodiment of the second electrode of FIG. 1.

FIGS. 3 and 4 are diagrams for explaining the control of an electric field controller in order to convert an electronic device of FIG. 1 into a first mode and a second mode.

FIGS. 5 to 9 are diagrams for explaining the conversion to the first mode and the second mode of the electronic device of FIG. 1.

FIG. 10 is a schematic diagram illustrating an electronic device according to an embodiment of the present disclosure.

FIG. 11 is a schematic diagram illustrating an electronic device according to an embodiment of the present disclosure.

FIG. 12 is a schematic diagram illustrating an electronic device according to an embodiment of the present disclosure.

FIG. 13 is a schematic diagram illustrating an electronic device according to an embodiment of the present disclosure.

FIG. 14 is a schematic diagram illustrating an electronic device according to an embodiment of the present disclosure.

FIG. 15 is a schematic diagram illustrating an electronic device according to an embodiment of the present disclosure.

FIG. 16 is a plan view viewed from the H direction of FIG. 15.

FIG. 17 is a diagram for schematically explaining an energy band relationship of the electronic device of FIG. 15.

FIG. 18 is a schematic diagram illustrating an electronic device according to an embodiment of the present disclosure.

### MODE OF DISCLOSURE

Hereinafter, the configuration and operation of the present disclosure will be described in detail with reference to the embodiments of the present disclosure shown in the accompanying drawings.

Since the present disclosure can undergo various transformations and can have various embodiments, specific embodiments are illustrated in the drawings and described in detail in the detailed description. Effects and features of the present disclosure, and methods of achieving the same, will become apparent with reference to the embodiments described below in detail in conjunction with the drawings. However, the present disclosure is not limited to the embodiments disclosed below and may be implemented in various forms.

Hereinafter, embodiments of the present disclosure will be described in detail with reference to the accompanying drawings, and when described with reference to the drawings, the same or corresponding components are given with the same reference numerals, and the overlapping description thereof will be omitted.

In the following embodiments, terms such as first, second, etc. are used for the purpose of distinguishing one component from another component, not in the aspect of limitation.

In the following examples, the singular expression includes the plural expression unless the context clearly dictates otherwise.

In the following embodiments, terms such as “include” or “have” means that the features or components described in the specification are present, and the possibility that one or more other features or components can be added, is not excluded in advance.

In the drawings, the size of the components may be exaggerated or reduced for convenience of description. For example, since the size and thickness of each component shown in the drawings are arbitrarily indicated for convenience of description, the present disclosure is not necessarily limited to the configurations illustrated in the drawings.

In the following embodiments, the x-axis, the y-axis, and the z-axis are not limited to three axes on the Cartesian coordinate system, and may be interpreted in a broad sense including the same. For example, the x-axis, y-axis, and z-axis may be orthogonal to each other, but may refer to different directions that are not orthogonal to each other.

In cases where certain embodiments can be implemented in different manners, a specific process sequence may be performed different from the described sequence. For example, two processes described in succession may be performed substantially simultaneously, or may be performed in an order opposite to the order described.

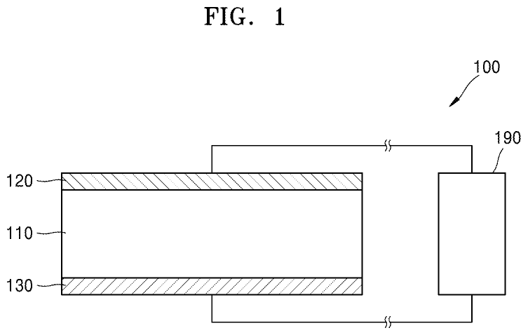

FIG. 1 is a schematic diagram illustrating an electronic device 100 according to an embodiment of the present disclosure.

Referring to FIG. 1, the electronic device 100 according to an embodiment may include a first electrode part 120, a second electrode part 130, an active layer 110, and an electric field controller 190.

The first electrode part 120 may include a conductive material.

For example, the first electrode part 120 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the first electrode part 120 may be formed using a conductive metal oxide. In an embodiment, the first electrode part 120 may include strontium ruthenium oxide (SrRuO₃).

In an embodiment, the first electrode part 120 may include (LaxSry)CoOz, for example, (La_{0.5}Sr_{0.5})CoO₃. In an embodiment, the first electrode part 120 may include LaCoO₃.

The second electrode part 130 may include a conductive material and may be spaced apart from the first electrode part 120.

For example, the second electrode part 130 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the second electrode part 130 may be formed using a conductive metal oxide. In an embodiment, the second electrode part 130 may include strontium ruthenium oxide (SrRuO₃).

In an embodiment, the second electrode part 130 may include (LaxSry)CoOz, for example, (La_{0.5}Sr_{0.5})CoO₃. In an embodiment, the second electrode part 130 may include LaCoO₃.

The first electrode part 120 and the second electrode part 130 may be formed to have different characteristics.

In an embodiment, the first electrode part 120 and the second electrode part 130 may have different electrical characteristics. In an embodiment, the work function value of the first electrode part 120 may be different from the work function value of the second electrode part 130.

In an optional embodiment, the first electrode part 120 and the second electrode part 130 may include different materials.

In an embodiment, the first electrode part 120 may include platinum (Pt) and the second electrode part 130 may include gold (Au). In an embodiment, the first electrode part 120 may include platinum (Pt) and the second electrode part 130 may include platinum (Pt). may include strontium ruthenium oxide (SrRuO₃).

In an embodiment, the first electrode part 120 may include (LaxSry)CoOz, for example, (La_{0.5}Sr_{0.5})CoO₃, and the second electrode part 130 may include LaCoO₃.

In one or more embodiments, the first electrode part 120 and the second electrode part 130 may be formed using various materials to have different characteristics.

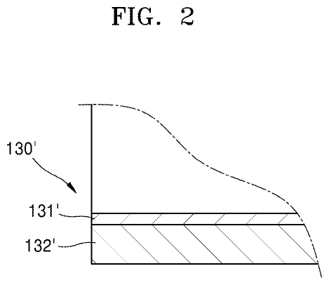

FIG. 2 is a diagram illustrating an optional embodiment of the second electrode of FIG. 1.

Referring to FIG. 2, the second electrode part 130′ may be formed in multiple layers.

For example, the second electrode part 130′ may include a first layer 131′ and a second layer 132′, and the first layer 131′ may be disposed to face the active layer 110. In an embodiment, the first layer 131′ may contact the active layer 110.

The first layer 131′ may be formed of a material different from that of the first electrode part 120, and the second layer 132′ may include a material different from that of the first layer 131′. For example, the second layer 132′ may be formed of the same material as the first electrode part 120.

In an embodiment, the first electrode part 120 may include platinum (Pt), the first layer 131′ of a second electrode part 130′ may include strontium ruthenium oxide (SrRuO₃), and the second layer 132′ may include platinum (Pt).

The active layer 110 may be disposed between the first electrode part 120 and the second electrode part 130.

The active layer 110 may include a spontaneously polarizable material.

For example, the active layer 110 may include a ferroelectric material, and may include a material that has spontaneous electrical polarization (electric dipole) which can be reversed in the presence of an electric field.

In an optional embodiment, the active layer 110 may include a perovskite-based material, for example, BaTiO₃, SrTiO₃, BiFe₃, PbTiO₃, PbZrO₃, or SrBi₂Ta₂O₉.

In an embodiment, the active layer 110 has the structure of an ABX3 structure, A may include an alkyl group of CnH2n+1, and one or more materials selected from inorganic materials such as Cs and Ru that can form a perovskite solar cell structure, B may include one or more materials selected from Pb, Sn, Ti, Nb, Zr, and Ce, and X may include a halogen material. For example, the active layer 110 may include CH₃NH₃PbI₃, CH₃NH₃PbIₓCl₃₋ₓ, MAPbI₃, CH₃NH₃PbIₓBr₃₋ₓ, CH₃NH₃PbClxBr₃₋ₓ, HC(NH₂)₂PbI₃, HC(NH₂)₂PbIₓCl₃₋ₓ, HC(NH₂)₂PbIₓBr₃₋ₓ, HC(NH₂)₂PbClₓBr₃₋ₓ, (CH₃NH₃)(HC(NH₂)₂)_{1-y}PbI₃, (CH₃NH₃)(HC(NH₂)₂)_{1-y}PbIₓCl₃₋ₓ, (CH₃NH₃)(HC(NH₂)₂)_{1-y}PbIₓBr₃₋ₓ, or (CH₃NH₃)(HC(NH₂)₂)_{1-y}PbCIₓBr₃₋ₓ (0≤x, y≤1).

The active layer 110 may be formed using various other ferroelectric materials, and descriptions of all examples thereof will be omitted. In addition, when the active layer 110 is formed, the ferroelectric material may be doped with various other materials to include additional functions or to improve electrical properties.

The active layer 110 has spontaneous polarization and may control the degree and direction of polarization according to application of an electric field. In addition, the active layer 110 may maintain a polarized state even when the applied electric field is removed.

The active layer 110 may be formed to optionally have a first mode having a first electrical resistance and a second mode having a value that is smaller than the first electrical resistance.

Specific details on this will be described later.

The electric field controller 190 may be connected to the first electrode part 120 and the second electrode part 130 to apply an electric field.

Also, the direction of the electric field may be controlled through the electric field controller 190. For example, an electric field is applied to the active layer 110 connected to the first electrode part 120 and the second electrode part 130 through the electric field controller 190, and due to the electric field, the active layer 110 may be polarized in one direction, and by changing the direction of the electric field, the polarization direction of the active layer 110 may be controlled to be opposite thereto.

In an optional embodiment, the intensity of the electric field may be controlled by the electric field controller 190.

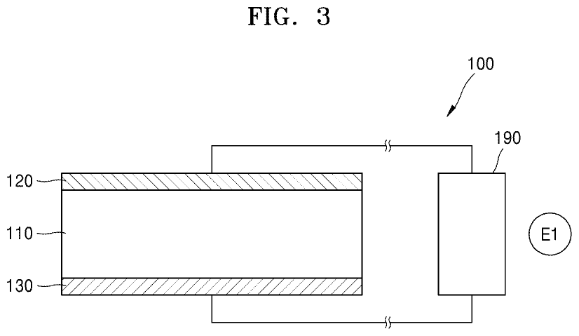

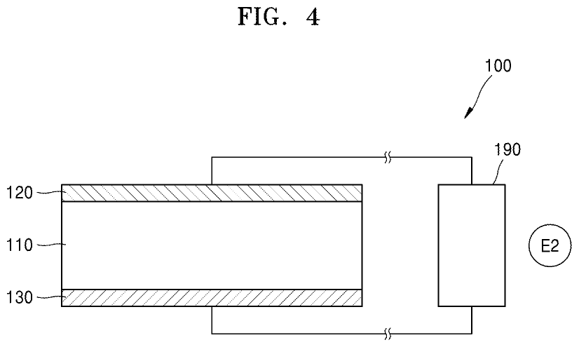

FIGS. 3 and 4 are diagrams for explaining the control of an electric field controller in order to convert an electronic device of FIG. 1 into a first mode and a second mode.

Referring to FIG. 3, a first electric field E1 is applied to the first electrode part 120 and the second electrode part 130 through the electric field controller 190 of the electronic device 100. When the first electric field E1 is applied to the first electrode part 120 and the second electrode part 130, the active layer 110 connected to the first electrode part 120 and the second electrode part 130 may be polarized in a first polarization direction.

Referring to FIG. 4, a second electric field E2 is applied to the first electrode part 120 and the second electrode part 130 through the electric field controller 190 of the electronic device 100.

The second electric field E2 may be an electric field in a direction different from that of the first electric field E1. For example, the direction of the second electric field E2 may be opposite to the direction of the first electric field E1.

When the second electric field E2 is applied to the first electrode part 120 and the second electrode part 130, the active layer 110 connected to the first electrode part 120 and the second electrode part 130 may be polarized in a second polarization direction, which is opposite to the first polarization direction.

In this case, for example, the intensity of the second electric field E2 may have the same value as the intensity of the first electric field E1.

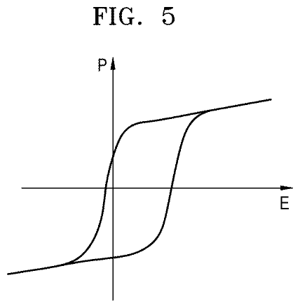

FIGS. 5 to 9 are diagrams for explaining the conversion to the first mode and the second mode of the electronic device 100 of FIG. 1.

FIG. 5 shows a polarization hysteresis curve when an electric field is applied to the first electrode part 120 and the second electrode part 130 through the electric field controller 190 of the electronic device 100.

Referring to FIG. 5, the horizontal axis represents an electric field (E) and the vertical axis represents a polarization (P).

Referring to FIG. 5, the polarization hysteresis curve of the electronic device 100 does not have a symmetrical shape. For example, referring to FIG. 5, a first polarization value (positive Y-intercept value) after applying and removing a positive electric field (e.g., the first electric field E1) is different from a second polarization value (negative Y-intercept value) after applying and removing a negative electric field (e.g., a second electric field E2), and the first polarization value (positive Y-intercept value) may be smaller than the second polarization value (negative Y-intercept value).

The difference in polarization values may be formed by controlling symmetrical electric field induction due to different characteristics of the first electrode part 120 and the second electrode part 130 as described above.

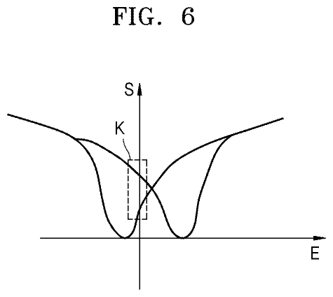

FIG. 6 shows a displacement hysteresis curve when an electric field is applied to the first electrode part 120 and the second electrode part 130 through the electric field controller 190 of the electronic device 100.

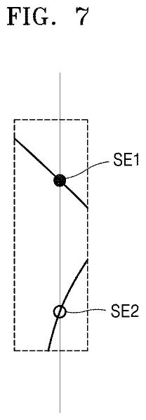

FIG. 7 is an enlarged view of portion K of FIG. 6.

In the active layer 110 of this embodiment, by applying an electric field, a polarized structure may be formed, and displacement may occur.

Referring to FIGS. 6 and 7, the horizontal axis represents the electric field E and the vertical axis represents the displacement S.

Referring to FIGS. 6 and7, the displacement hysteresis curve of the electronic device 100 does not have a symmetrical shape. For example, referring to FIG. 5, a first displacement SE1 after applying and removing a positive electric field (e.g., the first electric field E1) is different from a second displacement SE2 after applying and removing a negative electric field (e.g., a second electric field E2), and the size of the first displacement SE1 may be greater than the size of the second displacement SE2.

According to the difference in the polarization values of FIG. 5, the displacement values may have an asymmetric diagram and may be different from each other when different directions of the first electric field E1 and the second electric field E2 are applied and removed.

Through this, the deformation state that occurs after applying an electric field to the electronic device 100 and removing the same, may have two states instead of one state.

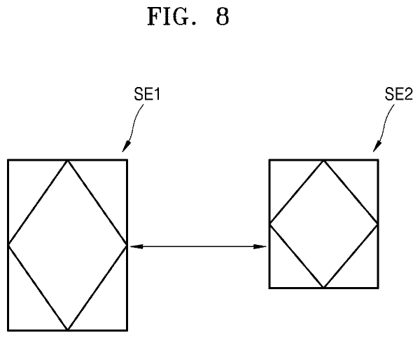

For example, as shown in FIG. 8, the active layer 110 of the electronic device 100 may have two displacement states.

Specifically, referring to FIG. 8, the active layer 110 may optionally have a first displacement (SE1) and a second displacement (SE2). The magnitude of the first displacement SE1 may be greater than the magnitude of the second displacement SE2.

For example, as described above, the direction of the electric field is controlled using the electric field controller 190 of the electronic device 100, and accordingly, the polarization direction formed in the active layer 110 is controlled to have a polarization shape as shown in FIG. 5 and a displacement shape as shown in FIG. 6.

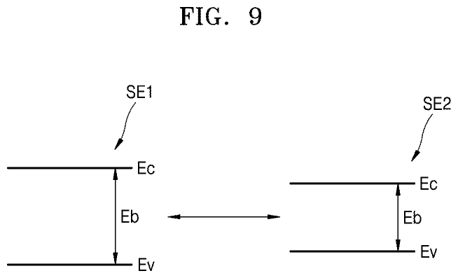

FIG. 9 shows a diagram illustrating a change in an energy bandgap according to an optional change in a displacement value of the active layer 110 of FIG. 8.

Referring to FIG. 9, when the active layer 110 has the first displacement SE1, the value of the energy bandgap of the active layer 110 may be greater than the value of the energy bandgap of the active layer 110 when the active layer 110 has the second displacement SE2.

Since the active layer 110 optionally has different energy band values, the active layer 110 may optionally have two different electrical resistance values.

For example, when the active layer 110 has the first displacement SE1, the active layer 110 may have a state (first mode) having a first electrical resistance. For example, when the active layer 110 has the second displacement SE2, the active layer 110 may have a state (second mode) having a second electrical resistance.

The active layer 110 may optionally have a state having the first electrical resistance (first mode) and a state having a second electrical resistance (second mode).

For example, as described above, the polarization form of the active layer 110 is controlled by controlling the direction of the electric field through the electric field controller 190 (see FIG. 5), and the displacement form is controlled according to the polarization form (see FIGS. 6 and 7), and thus, the energy bandgap value of the active layer 110 is optionally determined correspondingly (see FIG. 9) and thus, a first mode of high resistance or a second mode of low resistance may be optionally obtained.

In an electronic device according to an embodiment, an active layer may be disposed between a first electrode part and a second electrode part. In an embodiment, a first electrode part and a second electrode part contact an active layer. Although not illustrated as an optional embodiment, a conductive insertion layer may be formed between the first electrode part and the active layer or between the second electrode part and the active layer.

Through this structure, an electric field may be applied to the active layer, and accordingly, a polarization form in the first polarization direction may be obtained, and by controlling the direction of an electric field, a polarization form that is opposite to the first polarization direction, may be obtained.

In an embodiment, the first electrode part and the second electrode part may have different characteristics. For example, the first electrode part and the second electrode part may include different materials. Through this, an asymmetric electrical characteristic may be induced in the active layer.

Due to the different characteristics of the first electrode part and the second electrode part, for example, the asymmetry between electrodes, when an electric field is applied in different directions, and even when the intensity of the electric field is the same, the magnitude of the polarization in the first polarization direction at the removal time point of the electric field may be different from the magnitude of the polarization in the first polarization direction at the removal time point of the electric field.

Also, the active layer may have a polarization in response to polarization, and may have two different displacements after an electric field is applied and removed. For example, a first displacement value when a first electric field is applied and then removed may be different from a second displacement value when a second electric field is applied and then removed.

Also, a first electrical resistance value of the active layer in the state corresponding to the first displacement may be different from a second electrical resistance value of the active layer in the state corresponding to the second displacement. In an embodiment, the first electrical resistance value may be greater than the second electrical resistance value.

As a result, the active layer may optionally have one of a first mode having a relatively high electrical resistance value and a second mode having a relatively low electrical resistance value.

For example, the first mode when the first electric field is applied and then removed, may be maintained, and the second mode when the second electric field is applied and then removed, may be maintained.

Through this, an active layer having the first mode and the second mode which have different resistances, can be easily implemented, and an electronic device having such an active layer can be used for various purposes.

In an embodiment, the electronic device may be used as an electrical switching structure, and a memory and other various electronic circuit components can be implemented in which the first mode, in which the active layer has a high resistance value, corresponds to OFF, and the second mode, in which the active layer has a low resistance value, corresponds to ON.

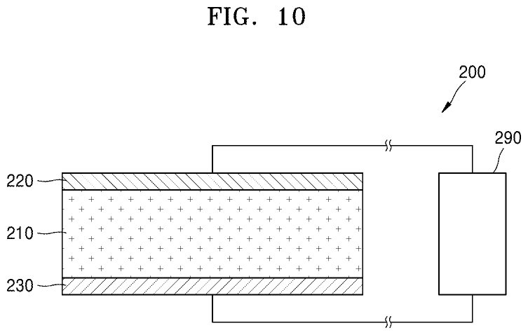

FIG. 10 is a schematic diagram illustrating an electronic device 200 according to an embodiment of the present disclosure.

Referring to FIG. 10, the electronic device 200 according to an embodiment may include a first electrode part 220, a second electrode part 230, an active layer 210, and an electric field controller 290.

The first electrode part 220 may include a conductive material.

For example, the first electrode part 220 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the first electrode part 220 may be formed using a conductive metal oxide. In an embodiment, the first electrode part 220 may include strontium ruthenium oxide (SrRuO₃).

In an embodiment, the first electrode part 220 may include (LaxSry)CoOz, for example, (La_{0.5}Sr_{0.5})CoO₃. In an embodiment, the first electrode part 220 may include LaCoO₃.

The second electrode part 230 may include a conductive material and may be spaced apart from the first electrode part 220.

For example, the second electrode part 230 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the second electrode part 230 may be formed using a conductive metal oxide. In an embodiment, the second electrode part 230 may include strontium ruthenium oxide (SrRuO₃).

In an embodiment, the second electrode part 230 may include (LaxSry)CoOz, for example, (La_{0.5}Sr_{0.5})CoO₃. In an embodiment, the second electrode part 230 may include LaCoO₃.

In an optional embodiment, the first electrode part 220 and the second electrode part 230 may be formed to have identical characteristics.

In an embodiment, the first electrode part 220 and the second electrode part 230 may have different electrical properties. In an embodiment, the first electrode part 220 and the second electrode part 230 may include the same material.

In an optional embodiment, the first electrode part 220 or the second electrode part 230 may have a stacked form.

The active layer 210 may be disposed between the first electrode part 220 and the second electrode part 230.

The active layer 210 may include a spontaneously polarizable material.

For example, the active layer 210 may include a ferroelectric material, and may include a material that has spontaneous electrical polarization (electric dipole) which can be reversed in the presence of an electric field.

In an optional embodiment, the active layer 210 may include a perovskite-based material, for example, BaTiO₃, SrTiO₃, BiFe₃, PbTiO₃, PbZrO₃, or SrBi₂Ta₂O₉.

In an embodiment, the active layer 210 has the structure of an ABX3 structure, A may include an alkyl group of CnH2n+1, and one or more materials selected from inorganic materials such as Cs and Ru that can form a perovskite solar cell structure, B may include one or more materials selected from Pb, Sn, Ti, Nb, Zr, and Ce, and X may include a halogen material. For example, the active layer 210 may include CH₃NH₃PbI₃, CH₃NH₃PbIₓCl₃₋ₓ, MAPbI₃, CH₃NH₃PbIₓBr₃₋ₓ, CH₃NH₃PbCIxBr₃₋ₓ, HC(NH₂)₂PbI₃, HC(NH₂)₂PbIₓCl₃₋ₓ, HC(NH₂)₂PbIₓBr₃₋ₓ, HC(NH₂)₂PbCIₓBr₃₋ₓ, (CH₃NH₃)(HC(NH₂)₂)_{1-y}PbI₃, (CH₃NH₃)(HC(NH₂)₂)_{1-y}PbIₓCl₃₋ₓ, (CH₃NH₃)(HC(NH₂)₂)_{1-y}PbIₓBr₃₋ₓ, or (CH₃NH₃)(HC(NH₂)₂)_{1-y}PbClₓBr₃₋ₓ (0≤x, y≤1).

The active layer 210 may be formed using various other ferroelectric materials, and descriptions of all examples thereof will be omitted. In addition, when the active layer 210 is formed, the ferroelectric material may be doped with various other materials to include additional functions or to improve electrical properties.

The active layer 210 has spontaneous polarization and may control the degree and direction of polarization according to application of an electric field. In addition, the active layer 210 may maintain a polarized state even when the applied electric field is removed.

An ion implantation region may be formed in one region of the active layer 210.

For example, an ion implantation process may be performed on a surface of the active layer 210 facing the first electrode part 220 using, for example, an ion implantation method in which a dopant is implanted.

In an embodiment, an ion implantation process may be performed on a surface of the active layer 210 facing the second electrode part 230 using, for example, an ion implantation method in which a dopant is implanted.

Ion implantation into the active layer 210 may be performed using various materials.

In an optional embodiment, an ion implantation region may be formed using a transition metal in the active layer 210.

In addition, an ion implantation region may be formed using ytterbium (Yb) or fluorine (F) in the active layer 210.

The active layer 210 may be formed to optionally have a first mode having a first electrical resistance and a second mode having a value that is smaller than the first electrical resistance.

Specific details on this will be described later.

The electric field controller 290 may be connected to the first electrode part 220 and the second electrode part 230 to apply an electric field.

Also, the direction of the electric field may be controlled through the electric field controller 290. For example, an electric field is applied to the active layer 210 connected to the first electrode part 220 and the second electrode part 230 through the electric field controller 290, and due to the electric field, the active layer 210 may be polarized in one direction, and by changing the direction of the electric field, the polarization direction of the active layer 210 may be controlled to be opposite thereto.

In an optional embodiment, the intensity of the electric field may be controlled by the electric field controller 290.

An operation of selecting the first mode and the second mode of the active layer 210 by controlling the electric field of the electronic device 200 will be described.

When a first electric field E1 is applied to the first electrode part 220 and the second electrode part 230 through the electric field controller 290 of the electronic device 200, the active layer 210 connected to the first electrode part 220 and the second electrode part 230 may be polarized in a first polarization direction.

In addition, a second electric field E2 may be applied to the first electrode part 220 and the second electrode part 230 through the electric field controller 290 of the electronic device 200.

The second electric field E2 may be an electric field in a direction different from that of the first electric field E1. For example, the direction of the second electric field E2 may be opposite to the direction of the first electric field E1.

When the second electric field E2 is applied to the first electrode part 220 and the second electrode part 230, the active layer 210 connected to the first electrode part 220 and the second electrode part 230 may be polarized in a second polarization direction, which is opposite to the first polarization direction.

In this case, for example, the intensity of the second electric field E2 may have the same value as the intensity of the first electric field E1.

The polarization hysteresis curve of the electronic device 200 according to the present embodiment does not have a symmetrical shape. For example, as shown in FIG. 5, a first polarization value (a positive Y-intercept value in the polarization hysteresis curve) after application and removal of a positive electric field (e.g., the first electric field E1) may be different from a second polarization value (a negative Y-intercept value in polarization hysteresis curve) after application and removal of a negative electric field (e.g., a second electric field E2). In an embodiment, the size of the first polarization value (a positive Y-intercept value in the polarization hysteresis curve) may be smaller than the size of the second polarization value (a negative Y-intercept value in the polarization hysteresis curve).

The difference in polarization values may be due to an ion implantation region formed in one region of the active layer 210, for example, a surface thereof facing the first electrode part 220 or a surface thereof facing the second electrode 230 as described above.

For example, surface properties, such as charge concentration, of the surface of the active layer 210 adjacent to the first electrode part 220 or the second electrode part 230 may be changed due to the ion implanted region, and as a result, even when the first electrode part 220 and the second electrode part 230 include the same material, the application of an electric field through the electric field controller 290, for example, the application of a first electric field and a second electric field which is opposite to the first electric field may lead to a difference in polarization.

The difference in polarization affects the displacement characteristics, and for example, as shown in FIG. 6, when an electric field is applied, a displacement may occur in the active layer 210 of the present embodiment.

In an embodiment, the displacement hysteresis curve of the electronic device 200 may not have a symmetrical shape, and the first displacement SE1 after application and removal of a positive electric field (e.g., first electric field E1) may be different from the second displacement SE2 after application and removal of a negative electric field (e.g., second electric field E2), and for example, the size of the first displacement SE1 may be greater than the size of the second displacement SE2.

According to the difference in the polarization values, the displacement values may have an asymmetric diagram and may be different from each other when different directions of the first electric field E1 and the second electric field E2 are applied and removed, and as a result, the deformation state that occurs after applying an electric field to the electronic device 200 and removing the same, may have two states instead of one state.

For example, as shown in FIG. 8, the active layer 210 of the electronic device 200 may have two displacement states.

Specifically, the active layer 210 may optionally have a first displacement SE1 and a second displacement SE2, and may have the size of the first displacement SE1 may be greater than the size of the second displacement SE2.

For example, as described above, the direction of the electric field is controlled using the electric field controller 290 of the electronic device 200, and accordingly, the polarization direction formed in the active layer 210 is controlled to have a polarization shape, and when electric field is removed to correspond thereto, different two displacement states may be obtained.

In addition, the value of the energy bandgap of the active layer 210 when the active layer 210 has a large first displacement SE1, may be greater than the value of the energy bandgap of the active layer 210 when the active layer 210 has a second displacement SE2 having a smaller value than the first displacement SE1.

Since the active layer 210 optionally has different energy band values, the active layer 210 may optionally have two different electrical resistance values.

For example, when the active layer 210 has the first displacement SE1, the active layer 210 may have a state (first mode) having a first electrical resistance. For example, when the active layer 210 has the second displacement SE2, the active layer 210 may have a state (second mode) having a second electrical resistance.

The active layer 210 may optionally have a state having the first electrical resistance (first mode) and a state having a second electrical resistance (second mode).

For example, as described above, the polarization form of the active layer 210 is controlled by controlling the direction of the electric field through the electric field controller 290, and the displacement form is controlled according to the polarization form, and thus, the energy bandgap value of the active layer 210 is optionally determined correspondingly and thus, a first mode of high resistance or a second mode of low resistance may be optionally obtained.

In an electronic device according to an embodiment, an active layer may be disposed between a first electrode part and a second electrode part. In an embodiment, a first electrode part and a second electrode part contact an active layer. Although not illustrated as an optional embodiment, a conductive insertion layer may be formed between the first electrode part and the active layer or between the second electrode part and the active layer.

Through this structure, an electric field may be applied to the active layer, and accordingly, a polarization form in the first polarization direction may be obtained, and by controlling the direction of an electric field, a polarization form that is opposite to the first polarization direction, may be obtained.

Also, in an embodiment, a doping process may be performed using various materials on one surface of the active layer, for example, one surface thereof facing a first electrode part or one surface thereof facing a second electrode part.

Through this doping process, the interface properties between the active layer and the first electrode part may be changed differently from the interface properties between the active layer and the second electrode part. Due to the change in these interface properties, the electric field inside the active layer may be induced asymmetrically.

Due to such properties of the active layer, for example, electrical asymmetry, when an electric field is applied in different directions, and even when the intensity of the electric field is the same, the magnitude of the polarization in the first polarization direction at the removal time point of the electric field may be different from the magnitude of the polarization in the first polarization direction at the removal time point of the electric field.

Also, the active layer may have a polarization in response to polarization, and may have two different displacements after an electric field is applied and removed. For example, a first displacement value when a first electric field is applied and then removed may be different from a second displacement value when a second electric field is applied and then removed.

Also, a first electrical resistance value of the active layer in the state corresponding to the first displacement may be different from a second electrical resistance value of the active layer in the state corresponding to the second displacement. In an embodiment, the first electrical resistance value may be greater than the second electrical resistance value.

As a result, the active layer may optionally have one of a first mode having a relatively high electrical resistance value and a second mode having a relatively low electrical resistance value.

For example, the first mode when the first electric field is applied and then removed, may be maintained, and the second mode when the second electric field is applied and then removed, may be maintained.

Through this, an active layer having the first mode and the second mode which have different resistances, can be easily implemented, and an electronic device having such an active layer can be used for various purposes.

In an embodiment, the electronic device may be used as an electrical switching structure, and a memory and other various electronic circuit components can be implemented in which the first mode, in which the active layer has a high resistance value, corresponds to OFF, and the second mode, in which the active layer has a low resistance value, corresponds to ON.

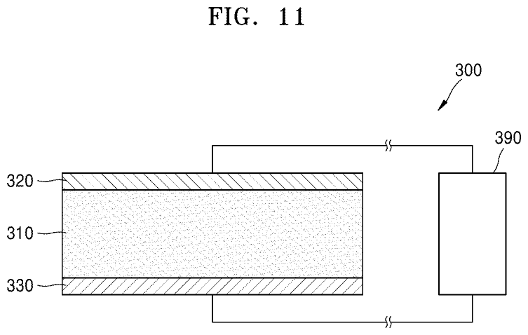

FIG. 11 is a schematic diagram illustrating an electronic device 300 according to an embodiment of the present disclosure.

Referring to FIG. 11, the electronic device 300 according to an embodiment may include a first electrode part 320, a second electrode part 330, an active layer 310, and an electric field controller 390.

The first electrode part 320 may include a conductive material.

For example, the first electrode part 320 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the first electrode part 320 may be formed using a conductive metal oxide. In an embodiment, the first electrode part 320 may include strontium ruthenium oxide (SrRuO₃).

In an embodiment, the first electrode part 320 may include (LaxSry)CoOz, for example, (La_{0.5}Sr_{0.5})CoO₃. In an embodiment, the first electrode part 320 may include LaCoO₃.

The second electrode part 330 may include a conductive material and may be spaced apart from the first electrode part 320.

For example, the second electrode part 330 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the second electrode part 330 may be formed using a conductive metal oxide. In an embodiment, the second electrode part 330 may include strontium ruthenium oxide (SrRuO₃).

In an embodiment, the second electrode part 330 may include (LaxSry)CoOz, for example, (La_{0.5}Sr_{0.5})CoO₃. In an embodiment, the second electrode part 330 may include LaCoO₃.

In an optional embodiment, the first electrode part 320 and the second electrode part 330 may be formed to have identical characteristics.

In an embodiment, the first electrode part 320 and the second electrode part 330 may have different electrical properties. In an embodiment, the first electrode part 320 and the second electrode part 330 may include the same material.

In an optional embodiment, the first electrode part 320 or the second electrode part 330 may have a stacked form.

The active layer 310 may be disposed between the first electrode part 320 and the second electrode part 330.

The active layer 310 may include a spontaneously polarizable material.

For example, the active layer 310 may include a ferroelectric material, and may include a material that has spontaneous electrical polarization (electric dipole) which can be reversed in the presence of an electric field.

In an optional embodiment, the active layer 310 may include a perovskite-based material, for example, BaTiO₃, SrTiO₃, BiFe₃, PbTiO₃, PbZrO₃, or SrBi₂Ta₂O₉.

In an embodiment, the active layer 310 has the structure of an ABX3 structure, A may include an alkyl group of CnH2n+1, and one or more materials selected from inorganic materials such as Cs and Ru that can form a perovskite solar cell structure, B may include one or more materials selected from Pb, Sn, Ti, Nb, Zr, and Ce, and X may include a halogen material. For example, the active layer 310 may include CH₃NH₃PbI₃, CH₃NH₃PbIₓCl₃₋ₓ, MAPbI₃, CH₃NH₃PbIₓBr₃₋ₓ, CH₃NH₃PbClxBr₃₋ₓ, HC(NH₂)₂PbI₃, HC(NH₂)₂PbIₓCl₃₋ₓ, HC(NH₂)₂PbIₓBr₃₋ₓ, HC(NH₂)₂PbClₓBr₃₋ₓ, (CH₃NH₃)(HC(NH₂)₂)_{1-y}PbI₃, (CH₃NH₃)(HC(NH₂)₂)_{1-y}PbIₓCl₃₋ₓ, (CH₃NH₃)(HC(NH₂)₂)_{1-y}PbIₓBr₃₋ₓ, or (CH₃NH₃)(HC(NH₂)₂)_{1-y}PbClₓBr₃₋ₓ (0≤x, y≤1).

The active layer 310 may be formed using various other ferroelectric materials, and descriptions of all examples thereof will be omitted. In addition, when the active layer 310 is formed, the ferroelectric material may be doped with various other materials to include additional functions or to improve electrical properties.

The active layer 310 has spontaneous polarization and may control the degree and direction of polarization according to application of an electric field. In addition, the active layer 310 may maintain a polarized state even when the applied electric field is removed.

A surface treatment region may be formed in one region of the active layer 310.

For example, a surface treatment region including an oxygen change region, for example, an oxygen deficient region may be formed in the surface of the active layer 310 facing the first electrode part 320 by performing a heat treatment process.

In an embodiment, a surface treatment region including an oxygen change region, for example, an oxygen deficient region may be formed in the surface of the active layer 310 facing the second electrode part 330 by performing a heat treatment process.

A surface treatment region which optionally including a surface treatment region may be formed in the region of the active layer 310 facing the first electrode part 320 or the region of the active layer 310 facing the second electrode part 330 so that the electric field characteristics inside the active layer 310 are asymmetrically implemented.

The active layer 310 may be formed to optionally have a first mode having a first electrical resistance and a second mode having a value that is smaller than the first electrical resistance.

Specific details on this will be described later.

The electric field controller 390 may be connected to the first electrode part 320 and the second electrode part 330 to apply an electric field.

Also, the direction of the electric field may be controlled through the electric field controller 390. For example, an electric field is applied to the active layer 310 connected to the first electrode part 320 and the second electrode part 330 through the electric field controller 390, and due to the electric field, the active layer 310 may be polarized in one direction, and by changing the direction of the electric field, the polarization direction of the active layer 310 may be controlled to be opposite thereto.

In an optional embodiment, the intensity of the electric field may be controlled by the electric field controller 390.

An operation of selecting the first mode and the second mode of the active layer 310 by controlling the electric field of the electronic device 300 will be described.

When a first electric field E1 is applied to the first electrode part 320 and the second electrode part 330 through the electric field controller 390 of the electronic device 300, the active layer 310 connected to the first electrode part 320 and the second electrode part 330 may be polarized in a first polarization direction.

In addition, a second electric field E2 may be applied to the first electrode part 320 and the second electrode part 330 through the electric field controller 390 of the electronic device 300.

The second electric field E2 may be an electric field in a direction different from that of the first electric field E1. For example, the direction of the second electric field E2 may be opposite to the direction of the first electric field E1.

When the second electric field E2 is applied to the first electrode part 320 and the second electrode part 330, the active layer 310 connected to the first electrode part 320 and the second electrode part 330 may be polarized in a second polarization direction, which is opposite to the first polarization direction.

In this case, for example, the intensity of the second electric field E2 may have the same value as the intensity of the first electric field E1.

The polarization hysteresis curve of the electronic device 300 according to the present embodiment does not have a symmetrical shape. For example, as shown in FIG. 5, a first polarization value (a positive Y-intercept value in the polarization hysteresis curve) after application and removal of a positive electric field (e.g., the first electric field E1) may be different from a second polarization value (a negative Y-intercept value in polarization hysteresis curve) after application and removal of a negative electric field (e.g., a second electric field E2). In an embodiment, the size of the first polarization value (a positive Y-intercept value in the polarization hysteresis curve) may be smaller than the size of the second polarization value (a negative Y-intercept value in the polarization hysteresis curve).

The difference in polarization values may be due to a surface treatment region formed in one region of the active layer 310, for example, a surface thereof facing the first electrode part 320 or a surface thereof facing the second electrode 330 as described above. In an embodiment, of the region of the active layer 310, the surface thereof adjacent to the first electrode part 320 or the second electrode part 330 may undergo oxygen deficiency due to the heat treatment process, and by controlling the formation of the oxygen deficient region, a surface treatment region having changed surface characteristics may be formed.

As a result, even in the case where the first electrode part 320 and the second electrode part 330 are formed of the same material, when the electric field is applied through the electric field controller 390, for example, the first electric field and the second electric field are applied in the opposite directions, the surface treatment region having changed surface characteristics may be formed.

The difference in polarization affects the displacement characteristics, and for example, as shown in FIG. 6, displacement may occur in the active layer 310 of the present embodiment by the application of an electric field.

In an embodiment, the displacement hysteresis curve of the electronic device 300 may not have a symmetrical shape, and the first displacement SE1 after application and removal of a positive electric field (e.g., first electric field E1) may be different from the second displacement SE2 after application and removal of a negative electric field (e.g., second electric field E2), and for example, the size of the first displacement SE1 may be greater than the size of the second displacement SE2.

That is, according to the difference in the polarization values, the displacement values may have an asymmetric diagram, and as the first electric field E1 and the second electric field E2 in opposite directions are applied and removed, different displacement values may be obtained. Accordingly, the number of the deformation states that occur after applying an electric field to the electronic device 300 and removing the same, may be two or more, not one.

For example, as shown in FIG. 8, the active layer 310 of the electronic device 300 may have two displacement states.

Specifically, the active layer 310 may optionally have a first displacement SE1 and a second displacement SE2, and may have the size of the first displacement SE1 may be greater than the size of the second displacement SE2.

For example, as described above, the direction of the electric field is controlled using the electric field controller 390 of the electronic device 300, and accordingly, the polarization direction formed in the active layer 310 is controlled to have a polarization shape, and when electric field is removed to correspond thereto, different two displacement states may be obtained.

In addition, the value of the energy bandgap of the active layer 310 when the active layer 310 has a large first displacement SE1, may be greater than the value of the energy bandgap of the active layer 310 when the active layer 310 has a second displacement SE2 having a smaller value than the first displacement SE1.

Since the active layer 310 optionally has different energy band values, the active layer 310 may optionally have two different electrical resistance values.

For example, when the active layer 310 has the first displacement SE1, the active layer 310 may have a state (first mode) having a first electrical resistance. For example, when the active layer 310 has the second displacement SE2, the active layer 310 may have a state (second mode) having a second electrical resistance.

The active layer 310 may optionally have a state having the first electrical resistance (first mode) and a state having a second electrical resistance (second mode).

For example, as described above, the polarization form of the active layer 310 is controlled by controlling the direction of the electric field through the electric field controller 390, and the displacement form is controlled according to the polarization form, and thus, the energy bandgap value of the active layer 310 is optionally determined correspondingly and thus, a first mode of high resistance or a second mode of low resistance may be optionally obtained.

In an electronic device according to an embodiment, an active layer may be disposed between a first electrode part and a second electrode part. In an embodiment, a first electrode part and a second electrode part contact an active layer. Although not illustrated as an optional embodiment, a conductive insertion layer may be formed between the first electrode part and the active layer or between the second electrode part and the active layer.

Through this structure, an electric field may be applied to the active layer, and accordingly, a polarization form in the first polarization direction may be obtained, and by controlling the direction of an electric field, a polarization form that is opposite to the first polarization direction, may be obtained.

In addition, in the present embodiment, a surface treatment region may be formed on one surface of the active layer, for example, one surface thereof facing the first electrode part or one surface thereof facing the second electrode part, and for example, an oxygen deficient region may be formed by a heat treatment process.

Through the formation of such a surface treatment region, the interface properties between the active layer and the first electrode part may be changed differently from the interface properties between the active layer and the second electrode part. Due to the change in these interface properties, the electric field inside the active layer may be induced asymmetrically.

Due to such properties of the active layer, for example, electrical asymmetry, when an electric field is applied in different directions, and even when the intensity of the electric field is the same, the magnitude of the polarization in the first polarization direction at the removal time point of the electric field may be different from the magnitude of the polarization in the first polarization direction at the removal time point of the electric field.

Also, the active layer may have a polarization in response to polarization, and may have two different displacements after an electric field is applied and removed. For example, a first displacement value when a first electric field is applied and then removed may be different from a second displacement value when a second electric field is applied and then removed.

Also, a first electrical resistance value of the active layer in the state corresponding to the first displacement may be different from a second electrical resistance value of the active layer in the state corresponding to the second displacement. In an embodiment, the first electrical resistance value may be greater than the second electrical resistance value.

As a result, the active layer may optionally have one of a first mode having a relatively high electrical resistance value and a second mode having a relatively low electrical resistance value.

For example, the first mode when the first electric field is applied and then removed, may be maintained, and the second mode when the second electric field is applied and then removed, may be maintained.

Through this, an active layer having the first mode and the second mode which have different resistances, can be easily implemented, and an electronic device having such an active layer can be used for various purposes.

In an embodiment, the electronic device may be used as an electrical switching structure, and a memory and other various electronic circuit components can be implemented in which the first mode, in which the active layer has a high resistance value, corresponds to OFF, and the second mode, in which the active layer has a low resistance value, corresponds to ON.

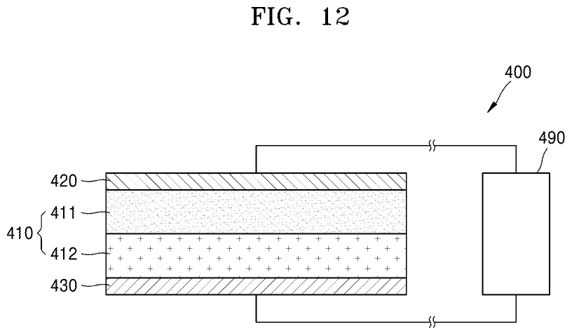

FIG. 12 is a schematic diagram illustrating an electronic device 400 according to an embodiment of the present disclosure.

Referring to FIG. 12, the electronic device 400 according to an embodiment may include a first electrode part 420, a second electrode part 430, an active layer 410, and an electric field controller 490.

The first electrode part 420 may include a conductive material.

For example, the first electrode part 420 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the first electrode part 420 may be formed using a conductive metal oxide. In an embodiment, the first electrode part 420 may include strontium ruthenium oxide (SrRuO₃).

In an embodiment, the first electrode part 420 may include (LaxSry)CoOz, for example, (La_{0.5}Sr_{0.5})CoO₃. In an embodiment, the first electrode part 420 may include LaCoO₃.

The second electrode part 430 may include a conductive material and may be spaced apart from the first electrode part 420.

For example, the second electrode part 430 may include aluminum (Al), chromium (Cr), copper (Cu), tantalum (Ta), titanium (Ti), molybdenum (Mo), tungsten (W), gold (Au), silver (Ag), or platinum (Pt).

In an embodiment, the second electrode part 430 may be formed using a conductive metal oxide. In an embodiment, the second electrode part 430 may include strontium ruthenium oxide (SrRuO₃).

In an embodiment, the second electrode part 430 may include (LaxSry)CoOz, for example, (La_{0.5}Sr_{0.5})CoO₃. In an embodiment, the second electrode part 430 may include LaCoO₃.

In an optional embodiment, the first electrode part 420 and the second electrode part 430 may be formed to have identical characteristics.

In an embodiment, the first electrode part 420 and the second electrode part 430 may have different electrical properties. In an embodiment, the first electrode part 420 and the second electrode part 430 may include the same material.

In an optional embodiment, the first electrode part 420 or the second electrode part 430 may have a stacked form.

The active layer 410 may be disposed between the first electrode part 420 and the second electrode part 430.

The active layer 410 may include a spontaneously polarizable material.

For example, the active layer 410 may include a ferroelectric material, and may include a material that has spontaneous electrical polarization (electric dipole) which can be reversed in the presence of an electric field.

The active layer 410 may include a first layer 411 and a second layer 412.

The first layer 411 may be adjacent to the first electrode part 420 and the second layer 412 may be adjacent to the second electrode part 430.

The first layer 411 of the active layer 410 may be disposed between the second layer 412 and the first electrode part 420.

In an optional embodiment, the first layer 411 of the active layer 410 may include a perovskite-based material, for example, BaTiO₃, SrTiO₃, BiFe₃, PbTiO₃, PbZrO₃, or SrBi₂Ta₂O₉.

In an embodiment, the first layer 411 of the active layer 410 has the structure of an ABX3 structure, A may include an alkyl group of CnH2n+1, and one or more materials selected from inorganic materials such as Cs and Ru that can form a perovskite solar cell structure, B may include one or more materials selected from Pb, Sn, Ti, Nb, Zr, and Ce, and X may include a halogen material. For example, the active layer 410 may include CH₃NH₃PbI₃, CH₃NH₃PbIₓCl₃₋ₓ, MAPbI₃, CH₃NH₃PbIₓBr₃₋ₓ, CH₃NH₃PbClxBr₃₋ₓ, HC(NH₂)₂PbI₃, HC(NH₂)₂PbIₓCl₃₋ₓ, HC(NH₂)₂PbIₓBr₃₋ₓ, HC(NH₂)₂PbClₓBr₃₋ₓ, (CH₃NH₃)(HC(NH₂)₂)_{1-y}PbI₃, (CH₃NH₃)(HC(NH₂)₂)_{1-y}PbIₓCl₃₋ₓ, (CH₃NH₃)(HC(NH₂)₂)_{1-y}PbIₓBr₃₋ₓ, or (CH₃NH₃)(HC(NH₂)₂)_{1-y}PbClₓBr₃₋ₓ (0≤x, y≤1).

The first layer 411 of the active layer 410 may be formed using various other ferroelectric materials, and descriptions of all examples thereof will be omitted. In addition, when the first layer 411 of the active layer 410 is formed, the ferroelectric material may be doped with various other materials to include additional functions or to improve electrical properties.

The second layer 412 of the active layer 410 may be disposed between the first layer 411 and the second electrode part 430.

In an optional embodiment, the second layer 412 of the active layer 410 may include a perovskite-based material, for example, BaTiO₃, SrTiO₃, BiFe₃, PbTiO₃, PbZrO₃, or SrBi₂Ta₂O₉.

In an embodiment, the second layer 412 of the active layer 410 has the structure of an ABX3 structure, A may include an alkyl group of CnH2n+1, and one or more materials selected from inorganic materials such as Cs and Ru that can form a perovskite solar cell structure, B may include one or more materials selected from Pb, Sn, Ti, Nb, Zr, and Ce, and X may include a halogen material. For example, the active layer 410 may include CH₃NH₃PbI₃, CH₃NH₃PbIₓCl₃₋ₓ, MAPbI₃, CH₃NH₃PbIₓBr₃₋ₓ, CH₃NH₃PbClxBr₃₋ₓ, HC(NH₂)₂PbI₃, HC(NH₂)₂PbIₓCl₃₋ₓ, HC(NH₂)₂PbIₓBr₃₋ₓ, HC(NH₂)₂PbClₓBr₃₋ₓ, (CH₃NH₃)(HC(NH₂)₂)_{1-y}PbI₃, (CH₃NH₃)(HC(NH₂)₂)_{1-y}PbIₓCl₃₋ₓ, (CH₃NH₃)(HC(NH₂)₂)_{1-y}PbIₓBr₃₋ₓ, or (CH₃NH₃)(HC(NH₂)₂)_{1-y}PbClₓBr₃₋ₓ (0≤x, y≤1).

The second layer 412 of the active layer 410 may be formed using various other ferroelectric materials, and descriptions of all examples thereof will be omitted. In addition, when the second layer 412 of the active layer 410 is formed, the ferroelectric material may be doped with various other materials to include additional functions or to improve electrical properties.

The active layer 410 has spontaneous polarization and may control the degree and direction of polarization according to application of an electric field. In addition, the active layer 410 may maintain a polarized state even when the applied electric field is removed.

The first layer 411 and the second layer 412 of the active layer 410 may have different characteristics.

The first layer 411 and the second layer 412 of the active layer 410 may have different materials.

In an optional embodiment, the first layer 411 of the active layer 410 may include one of the materials described above, for example, PbTiO₃, and the second layer 412 may include a material that is different from that of the first layer 411 from among the materials described above, for example, BaTiO₃.

As a result, a region of the active layer 410 facing the first electrode part 420 and a region of the active layer 410 facing the second electrode part 430 among the regions of the active layer 410 may have different characteristics, and the electric field characteristic inside the active layer 410 may be asymmetric.

The active layer 410 may be formed to optionally have a first mode having a first electrical resistance and a second mode having a value that is smaller than the first electrical resistance.

Specific details on this will be described later.

The electric field controller 490 may be connected to the first electrode part 420 and the second electrode part 430 to apply an electric field.

Also, the direction of the electric field may be controlled through the electric field controller 490. For example, an electric field is applied to the active layer 410 connected to the first electrode part 420 and the second electrode part 430 through the electric field controller 490, and due to the electric field, the active layer 410 may be polarized in one direction, and by changing the direction of the electric field, the polarization direction of the active layer 410 may be controlled to be opposite thereto.

In an optional embodiment, the intensity of the electric field may be controlled by the electric field controller 490.

An operation of selecting the first mode and the second mode of the active layer 410 by controlling the electric field of the electronic device 400 will be described.

When a first electric field E1 is applied to the first electrode part 420 and the second electrode part 430 through the electric field controller 490 of the electronic device 400, the active layer 410 connected to the first electrode part 420 and the second electrode part 430 may be polarized in a first polarization direction.

In addition, a second electric field E2 may be applied to the first electrode part 420 and the second electrode part 430 through the electric field controller 490 of the electronic device 400.

The second electric field E2 may be an electric field in a direction different from that of the first electric field E1. For example, the direction of the second electric field E2 may be opposite to the direction of the first electric field E1.

When the second electric field E2 is applied to the first electrode part 420 and the second electrode part 430, the active layer 410 connected to the first electrode part 420 and the second electrode part 430 may be polarized in a second polarization direction, which is opposite to the first polarization direction.

In this case, for example, the intensity of the second electric field E2 may have the same value as the intensity of the first electric field E1.

The polarization hysteresis curve of the electronic device 400 according to the present embodiment does not have a symmetrical shape. For example, as shown in FIG. 5, a first polarization value (a positive Y-intercept value in the polarization hysteresis curve) after application and removal of a positive electric field (e.g., the first electric field E1) may be different from a second polarization value (a negative Y-intercept value in polarization hysteresis curve) after application and removal of a negative electric field (e.g., a second electric field E2). In an embodiment, the size of the first polarization value (a positive Y-intercept value in the polarization hysteresis curve) may be smaller than the size of the second polarization value (a negative Y-intercept value in the polarization hysteresis curve).

The difference in the polarization values may be, as described above, due to the first layer 411 in one region of the active layer 410, for example, in a region thereof facing the first electrode part 420, and the second layer 412, which is different from the first layer 411, in one region of the active layer 410 facing the second electrode part 430.

In an embodiment, the first layer 411 of the active layer 410 may include PbTiO₃ as one of various materials of the active layer 410, and the second layer 412 may include a material that is different from that of the first layer 411 from among various materials of the active layer 410, for example, BaTiO₃, and as a result, even in the case where the first electrode part 420 and the second electrode part 430 are formed of the same material, when an electric field is applied through the electric field controller 490, for example, a first electric field and a second electric field of which direction is opposite to that of the first electric field, are applied, a difference in polarization values may occur.

The difference in polarization affects the displacement characteristics, and for example, as shown in FIG. 6, when an electric field is applied, a displacement may occur in the active layer 410 of the present embodiment.

In an embodiment, the displacement hysteresis curve of the electronic device 400 may not have a symmetrical shape, and the first displacement SE1 after application and removal of a positive electric field (e.g., first electric field E1) may be different from the second displacement SE2 after application and removal of a negative electric field (e.g., second electric field E2), and for example, the size of the first displacement SE1 may be greater than the size of the second displacement SE2.

That is, according to the difference in the polarization values, the displacement values may have an asymmetrical diagram, and as the first electric field E1 and the second electric field E2 in opposite directions are applied and removed, different displacement values may be obtained. Accordingly, the number of the deformation states that occur after applying an electric field to the electronic device 400 and removing the same, may be two or more, not one.

For example, as shown in FIG. 8, the active layer 410 of the electronic device 400 may have two displacement states.

Specifically, the active layer 410 may optionally have a first displacement SE1 and a second displacement SE2, and may have the size of the first displacement SE1 may be greater than the size of the second displacement SE2.

For example, as described above, the direction of the electric field is controlled using the electric field controller 490 of the electronic device 400, and accordingly, the polarization direction formed in the active layer 410 is controlled to have a polarization shape, and when electric field is removed to correspond thereto, different two displacement states may be obtained.

In addition, the value of the energy bandgap of the active layer 410 when the active layer 410 has a large first displacement SE1, may be greater than the value of the energy bandgap of the active layer 410 when the active layer 410 has a second displacement SE2 having a smaller value than the first displacement SE1.

Since the active layer 410 optionally has different energy band values, the active layer 410 may optionally have two different electrical resistance values.

For example, when the active layer 410 has the first displacement SE1, the active layer 410 may have a state (first mode) having a first electrical resistance. For example, when the active layer 410 has the second displacement SE2, the active layer 410 may have a state (second mode) having a second electrical resistance.

The active layer 410 may optionally have a state having the first electrical resistance (first mode) and a state having a second electrical resistance (second mode).

For example, as described above, the polarization form of the active layer 410 is controlled by controlling the direction of the electric field through the electric field controller 490, and the displacement form is controlled according to the polarization form, and thus, the energy bandgap value of the active layer 410 is optionally determined correspondingly and thus, a first mode of high resistance or a second mode of low resistance may be optionally obtained.

In an electronic device according to an embodiment, an active layer may be disposed between a first electrode part and a second electrode part. In an embodiment, a first electrode part and a second electrode part contact an active layer. Although not illustrated as an optional embodiment, a conductive insertion layer may be formed between the first electrode part and the active layer or between the second electrode part and the active layer.

Through this structure, an electric field may be applied to the active layer, and accordingly, a polarization form in the first polarization direction may be obtained, and by controlling the direction of an electric field, a polarization form that is opposite to the first polarization direction, may be obtained.

In addition, in the present embodiment, a first layer may be formed in one region of the active layer, for example, one region thereof facing a first electrode part, and a second layer may be formed in one region of the active layer facing a second electrode part, and the first layer and the second layer may include different materials.

Through the formation of the first layer and the second layer, the interface properties between the active layer and the first electrode part may be changed differently from the interface properties between the active layer and the second electrode part. Due to the change in these interface properties, the electric field inside the active layer may be induced asymmetrically.

Due to such properties of the active layer, for example, electrical asymmetry, when an electric field is applied in different directions, and even when the intensity of the electric field is the same, the magnitude of the polarization in the first polarization direction at the removal time point of the electric field may be different from the magnitude of the polarization in the first polarization direction at the removal time point of the electric field.

Also, the active layer may have a polarization in response to polarization, and may have two different displacements after an electric field is applied and removed. For example, a first displacement value when a first electric field is applied and then removed may be different from a second displacement value when a second electric field is applied and then removed.

Also, a first electrical resistance value of the active layer in the state corresponding to the first displacement may be different from a second electrical resistance value of the active layer in the state corresponding to the second displacement. In an embodiment, the first electrical resistance value may be greater than the second electrical resistance value.

As a result, the active layer may optionally have one of a first mode having a relatively high electrical resistance value and a second mode having a relatively low electrical resistance value.

For example, the first mode when the first electric field is applied and then removed, may be maintained, and the second mode when the second electric field is applied and then removed, may be maintained.

Through this, an active layer having the first mode and the second mode which have different resistances, can be easily implemented, and an electronic device having such an active layer can be used for various purposes.

In an embodiment, the electronic device may be used as an electrical switching structure, and a memory and other various electronic circuit components can be implemented in which the first mode, in which the active layer has a high resistance value, corresponds to OFF, and the second mode, in which the active layer has a low resistance value, corresponds to ON.

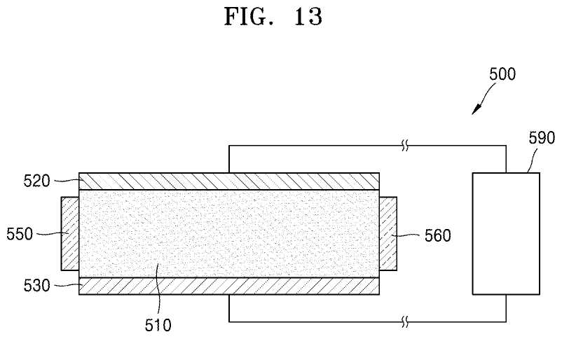

FIG. 13 is a schematic diagram illustrating an electronic device 500 according to an embodiment of the present disclosure.

Referring to FIG. 13, the electronic device 500 according to an embodiment may include a first electrode part 520, a second electrode part 530, an active layer 510, an electric field controller 590, a first connection electrode 550, and a second connection electrode 560.

The first electrode part 520, the second electrode part 530, the active layer 510, and the electric field controller 590 are the same as described in the electronic devices 100, 200, 300, and 400 of the embodiments of FIGS. 1 to 12, and if needed, may be modified and applied within similar ranges. Accordingly, a detailed description thereof will be omitted and will be described herein focusing on different parts.

The first connection electrode 550 and the second connection electrode 560 may each be formed on the surface of the active layer 510.

Also, the first connection electrode 550 and the second connection electrode 560 may be disposed to be spaced apart from the first electrode part 520 and the second electrode part 530, respectively.

For example, the first connection electrode 550 and the second connection electrode 560 may each be disposed on a surface of the active layer 510 on which the first electrode part 520 and the second electrode part 530 are not formed.

In an embodiment, the first connection electrode 550 and the second connection electrode 560 may each be disposed on a side surface of the active layer 510 on which the first electrode part 520 and the second electrode part 530 are not formed, and may be arranged to face each other.

The first connection electrode 550 and the second connection electrode 560 may be formed using various conductive materials. For example, the first connection electrode 550 and the second connection electrode 560 may each include aluminum, chromium, copper, tantalum, titanium, molybdenum, or tungsten.

In an optional embodiment, the first connection electrode 550 and the second connection electrode 560 may include a structure in which a plurality of conductive layers are stacked.

In an optional embodiment, the first connection electrode 550 and the second connection electrode 560 may each be formed using a conductive metal oxide, for example, indium oxide (e.g., In₂O₃), tin oxide (e.g., SnO₂), zinc oxide (e.g., ZnO), an indium tin oxide alloy (e.g., In₂O₃—SnO₂), or an indium zinc oxide alloy (e.g., In₂O₃—ZnO).

In an optional embodiment the first connection electrode 550 and the second connection electrode 560 may be a terminal member including input/output of electrical signals.

In an embodiment the first connection electrode 550 and the second connection electrode 560 may include a source electrode or a drain electrode.

In an electronic device according to an embodiment, an active layer may be disposed between a first electrode part and a second electrode part. In an embodiment, a first electrode part and a second electrode part contact an active layer. In addition, a first connection electrode and a second connection electrode may be formed on an active layer and may be spaced apart from a first electrode part and a second electrode part.

In the present embodiment, like the embodiments described above, an electric field may be asymmetrically induced, and as a result, in the case where an electric field is applied in different directions, even when the intensity of the electric field is the same, the magnitude of the polarization in the first polarization direction at the removal time point of the electric field may be different from the magnitude of the polarization in the first polarization direction at the removal time point of the electric field.

Accordingly, the active layer may have different first and second displacements, and the active layer may easily implement a first mode and a second mode which have different resistances.

Through this, in the first mode in which the active layer has a high resistance value and the second mode in which the active layer has a low resistance value, the flow of current between the first connection electrode and the second connection electrode may vary.

For example, in the first mode, in response to OFF, the flow of current between the first connection electrode and the second connection electrode may not occur or the flow of current may be less than a set reference, and in the second mode, in response of ON, the flow of current between the first connection electrode and the second connection electrode may occur or may exceed the set reference.

Through this, it is possible to easily control the flow of current between the first connection electrode and the second connection electrode of the electronic device.

As such, the electronic device can be applied to implement a memory and other various electronic circuit components.

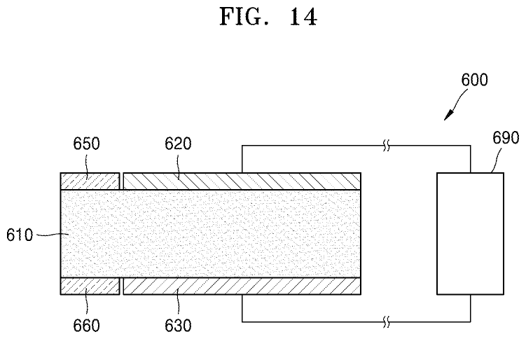

FIG. 14 is a schematic diagram illustrating an electronic device 600 according to an embodiment of the present disclosure.

Referring to FIG. 14, the electronic device 600 according to an embodiment may include a first electrode part 620, a second electrode part 630, an active layer 610, an electric field controller 690, a first connection electrode 650, and a second connection electrode 660.

The first electrode part 620, the second electrode part 630, the active layer 610, and the electric field controller 690 are the same as described in the electronic devices 100, 200, 300, and 400 of the embodiments of FIGS. 1 to 12, and if needed, may be modified and applied within similar ranges. Accordingly, a detailed description thereof will be omitted and will be described herein focusing on different parts.

The first connection electrode 650 and the second connection electrode 660 may each be formed on the surface of the active layer 510 and may be spaced apart from each other.

Also, the first connection electrode 650 and the second connection electrode 660 may be disposed to be spaced apart from the first electrode part 620 and the second electrode part 630, respectively.

For example, the first connection electrode 650 may be disposed to be spaced apart from the first electrode part 620 on an upper surface of the active layer 610. For example, the first electrode part 620 may be formed in one region of the upper surface of the active layer 610, and the first connection electrode 650 may be formed in another region of the upper surface of the active layer 610, which is different from the region on which the first electrode part 620 is formed.

For example, the second connection electrode 660 may be disposed to be spaced apart from the second electrode part 630 on a lower surface of the active layer 610. For example, the second electrode part 630 may be formed in one region of the lower surface of the active layer 610, and the second connection electrode 660 may be formed in another region of the lower surface of the active layer 610, which is different from the region on which the second electrode part 630 is formed.

The first connection electrode 650 and the second connection electrode 660 may be formed using various conductive materials. For example, the first connection electrode 650 and the second connection electrode 660 may each include aluminum, chromium, copper, tantalum, titanium, molybdenum, or tungsten.

In an optional embodiment, the first connection electrode 650 and the second connection electrode 660 may include a structure in which a plurality of conductive layers are stacked.

In an optional embodiment, the first connection electrode 650 and the second connection electrode 660 may each be formed using a conductive metal oxide, for example, indium oxide (e.g., In₂O₃), tin oxide (e.g., SnO₂), zinc oxide (e.g., ZnO), an indium tin oxide alloy (e.g., In₂O₃—SnO₂), or an indium zinc oxide alloy (e.g., In₂O₃—ZnO).

In an optional embodiment the first connection electrode 650 and the second connection electrode 660 may be a terminal member including input/output of electrical signals.

In an embodiment the first connection electrode 650 and the second connection electrode 660 may include a source electrode or a drain electrode.

In an electronic device according to an embodiment, an active layer may be disposed between a first electrode part and a second electrode part. In an embodiment, a first electrode part and a second electrode part contact an active layer. In addition, a first connection electrode and a second connection electrode may be formed on an active layer and may be spaced apart from a first electrode part and a second electrode part.

In addition, the first electrode part and the first connection electrode may be formed on one surface of the active layer, and the second electrode part and the second connection electrode may be formed on a surface of the active layer. Through this, it is possible to easily implement miniaturization or integration of an electronic device.

In addition, in some cases, the first electrode part and the first connection electrode may be formed by simultaneously patterning using the same material, and the second electrode part and the second connection electrode may be formed by simultaneously patterning using the same material. Accordingly, it is possible to improve the manufacturing characteristics of the electronic device and to easily form a fine line width structure by precise pattern formation.

In the present embodiment, like the embodiments described above, an electric field may be asymmetrically induced, and as a result, in the case where an electric field is applied in different directions, even when the intensity of the electric field is the same, the magnitude of the polarization in the first polarization direction at the removal time point of the electric field may be different from the magnitude of the polarization in the first polarization direction at the removal time point of the electric field.

Accordingly, the active layer may have different first and second displacements, and the active layer may easily implement a first mode and a second mode which have different resistances.

Through this, in the first mode in which the active layer has a high resistance value and the second mode in which the active layer has a low resistance value, the flow of current between the first connection electrode and the second connection electrode may vary.

For example, in the first mode, in response to OFF, the flow of current between the first connection electrode and the second connection electrode may not occur or the flow of current may be less than a set reference, and in the second mode, in response of ON, the flow of current between the first connection electrode and the second connection electrode may occur or may exceed the set reference.

Through this, it is possible to easily control the flow of current between the first connection electrode and the second connection electrode of the electronic device.

As such, the electronic device can be applied to implement a memory and other various electronic circuit components.

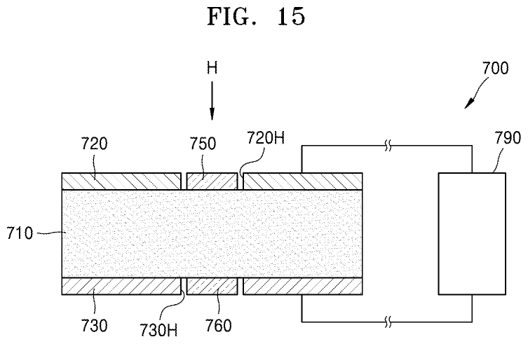

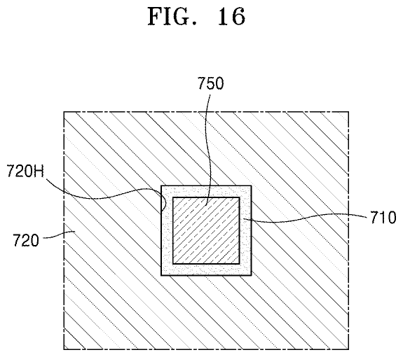

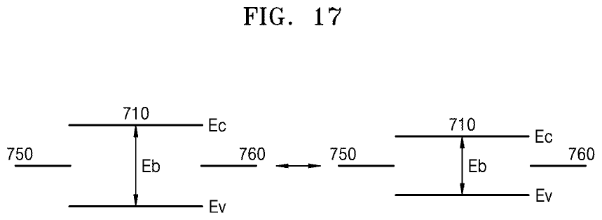

FIG. 15 is a schematic diagram illustrating an electronic device 700 according to an embodiment of the present disclosure, FIG. 16 is a plan view viewed from the H direction of FIG. 15, and FIG. 17 is a diagram for schematically explaining an energy band relationship of the electronic device of FIG. 15.

Referring to FIGS. 15 to 17, the electronic device 700 of this embodiment includes a first electrode part 720, a second electrode part 730, an active layer 710, an electric field controller 790, and a first connection electrode 750, and a second connection electrode 760.

The first electrode part 720, the second electrode part 730, the active layer 710, and the electric field controller 790 are the same as described in the electronic devices 100, 200, 300, and 400 of the embodiments of FIGS. 1 to 12, and if needed, may be modified and applied within similar ranges. Accordingly, a detailed description thereof will be omitted and will be described herein focusing on different parts.

The first connection electrode 750 and the second connection electrode 760 may each be formed on the surface of the active layer 710 and may be spaced apart from each other.

Also, the first connection electrode 750 and the second connection electrode 760 may be disposed to be spaced apart from the first electrode part 720 and the second electrode part 730, respectively.

For example, the first connection electrode 750 may be disposed to be spaced apart from the first electrode part 720 on an upper surface of the active layer 710. For example, the first connection electrode 750 may be formed in one region of the upper surface of the active layer 710, and the first electrode part 720 may be disposed to surround the first connection electrode 750 on the upper surface of the active layer 710.

The first electrode part 720 may include an open portion 720H, and the first connection electrode 750 may be disposed to be spaced apart from the first electrode part 720 in the open portion 720H.

In an embodiment, the second connection electrode 760 may be disposed to be spaced apart from the second electrode part 730 on a lower surface of the active layer 710. For example, the second connection electrode 760 may be formed in one region of a lower surface of the active layer 710, and the second electrode part 730 may be disposed to surround the second connection electrode 760 on the lower surface of the active layer 710.

The second electrode part 730 may include an open portion 730H, and the second connection electrode 760 may be disposed to be spaced apart from the second electrode part 730 in the open portion 730H.

The first connection electrode 750 and the second connection electrode 760 may be formed using various conductive materials. For example, the first connection electrode 750 and the second connection electrode 760 may each include aluminum, chromium, copper, tantalum, titanium, molybdenum, or tungsten.

In an optional embodiment, the first connection electrode 750 and the second connection electrode 760 may include a structure in which a plurality of conductive layers are stacked.

In an optional embodiment, the first connection electrode 750 and the second connection electrode 760 may each be formed using a conductive metal oxide, for example, indium oxide (e.g., In₂O₃), tin oxide (e.g., SnO₂), zinc oxide (e.g., ZnO), an indium tin oxide alloy (e.g., In₂O₃—SnO₂), or an indium zinc oxide alloy (e.g., In₂O₃—ZnO).

In an optional embodiment the first connection electrode 750 and the second connection electrode 760 may be a terminal member including input/output of electrical signals.

In an embodiment the first connection electrode 750 and the second connection electrode 760 may include a source electrode or a drain electrode.

FIG. 17 shows a diagram illustrating a change in an energy bandgap according to an optional change in a displacement value of the active layer 710 of the electronic device 700 of FIG. 15.

Referring to FIG. 17, when the active layer 710 has a first displacement SE1, the value of the energy bandgap Eb of the active layer 710 is illustrated on the left (e.g., in the first mode), and when the active layer 710 has a second displacement SE2, the value of the energy bandgap Eb of the active layer 710 is illustrated on the right (e.g., in second mode).

As shown in FIG. 17, as the displacement value of the active layer 710 changes, a difference occurs in the value of the energy bandgap of the active layer 710, and accordingly, it can be inferred that the characteristic of the flow of current between the first connection electrode 750 and the second connection electrode 760 might vary.

Although not shown, the drawing for explaining the energy band value of FIG. 17 can be applied to the structures of FIGS. 13 and 14.

In an electronic device according to an embodiment, an active layer may be disposed between a first electrode part and a second electrode part. In an embodiment, a first electrode part and a second electrode part contact an active layer. In addition, a first connection electrode and a second connection electrode may be formed on an active layer and may be spaced apart from a first electrode part and a second electrode part.

In addition, the first electrode part and the first connection electrode may be formed on one surface of the active layer, and the second electrode part and the second connection electrode may be formed on a surface of the active layer. Specifically, the first electrode part may be formed to surround the first connection electrode, and the second electrode part may be formed to surround the second connection electrode.

Through this, it is possible to easily implement miniaturization or integration of an electronic device.

In addition, in some cases, the first electrode part and the first connection electrode may be formed by simultaneously patterning using the same material, and the second electrode part and the second connection electrode may be formed by simultaneously patterning using the same material. Accordingly, it is possible to improve the manufacturing characteristics of the electronic device and to easily form a fine line width structure by precise pattern formation.

In the present embodiment, like the embodiments described above, an electric field may be asymmetrically induced, and as a result, in the case where an electric field is applied in different directions, even when the intensity of the electric field is the same, the magnitude of the polarization in the first polarization direction at the removal time point of the electric field may be different from the magnitude of the polarization in the first polarization direction at the removal time point of the electric field.

Accordingly, the active layer may have different first and second displacements, and the active layer may easily implement a first mode and a second mode which have different resistances.

Through this, in the first mode in which the active layer has a high resistance value and the second mode in which the active layer has a low resistance value, the flow of current between the first connection electrode and the second connection electrode may vary.

For example, in the first mode, in response to OFF, the flow of current between the first connection electrode and the second connection electrode may not occur or the flow of current may be less than a set reference, and in the second mode, in response of ON, the flow of current between the first connection electrode and the second connection electrode may occur or may exceed the set reference.

Through this, it is possible to easily control the flow of current between the first connection electrode and the second connection electrode of the electronic device.

As such, the electronic device can be applied to implement a memory and other various electronic circuit components.

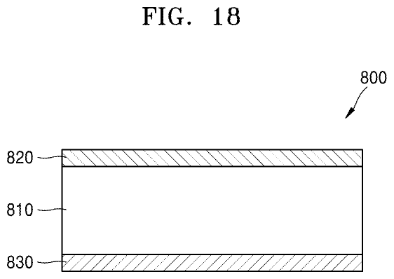

FIG. 18 is a schematic diagram illustrating an electronic device according to an embodiment of the present disclosure.

Referring to FIG. 18, the electronic device 800 of an embodiment may include a first electrode part 820, a second electrode part 830, and an active layer 810.

For convenience of description, the present embodiment will be described based on the difference from the embodiments provided above.

An electric field may be applied to the first electrode part 820 and the second electrode part 830 to control the polarization direction of the active layer 810 to a first polarization direction or a second polarization direction, and accordingly, the first mode and the second mode may optionally be provided.

For example, the active layer 810 may be allowed to have a first mode having a high resistance value and a second mode having a resistance value that is lower than the resistance of the first mode.

In this case, the first electrode part 820 and the second electrode part 830 may be applied as connection electrodes.

For example, an electric field is applied to the first electrode part 820 and the second electrode part 830 to be in the first mode having a high resistance value, and then, the electric field may be removed therefrom. Alternatively, without the removal of the electric field, it is possible to maintain an electric field smaller than an electric field sufficient to be in a second mode, which will be described later.

In this state, the first electrode part 820 and the second electrode part 830 may be used as a connection electrode, for example, a source electrode or a drain electrode, and in this case, no current flows or a current less than a set value flows so that the output value of a device or a memory may be output as OFF.

Then, the electric field applied to the first electrode part 820 and the second electrode part 830 may be controlled to be in a second mode having a low resistance value, and then the electric field may be removed. Alternatively, without the removal of the electric field, it is possible to maintain an electric field smaller than an electric field sufficient to be in the first mode.

In this state, the first electrode part 820 and the second electrode part 830 may be used as a connection electrode, for example, a source electrode or a drain electrode, and in this case, the current flows or a current of a set value or more flows so that the output value of a device or a memory may be output as ON.

Through this, it is possible to easily control the first mode and the second mode of the active layer by controlling the application of the electric field to the active layer through the first electrode part and the second electrode part of the electronic device, and depending on the first mode and the second mode, the flow of current between the first electrode part and the second electrode part as connection electrodes may be controlled so that the electronic device can be applied to implement a memory and other various electronic circuit components.

As described above, the present disclosure has been described with reference to the embodiments shown in the drawings, but the embodiments are provided only for illustrative purpose, and may be subjected to various modifications and equivalent levels of other embodiments, which would be obvious to those of ordinary skill in the art. Accordingly, the technical protection scope of the present disclosure should be determined by the technical concept of the claims appended herein.

The specific implementations described in the embodiments are only embodiments, and do not limit the scope of the embodiments in any aspects. In addition, unless there is a specific reference such as “essential” or “important” etc., components modified therewith may not be components essential for application of the present disclosure.

The use of “the” and referential terms that are similar thereto in the specification of the embodiments (especially in the claims may correspond to both the singular form and the plural form. In addition, when a range is described in the embodiments, this case includes disclosures to which individual values falling within the range are applied (unless there is a description to the contrary), and it is as if each individual value constituting the range would be set forth in the detailed description. Finally, the steps constituting the method according to the embodiments may be performed in an appropriate order unless the order is explicitly stated or there is no description to the contrary. Embodiments are not necessarily limited according to the order of description of the steps. The use of all examples or exemplary terms (e.g., etc.) in the embodiments are merely for describing the embodiments in detail, and unless being limited by the claims, the scope of the embodiments is not limited by the examples or exemplary terminology. In addition, those skilled in the art will recognize that various modifications, combinations, and changes may be made in accordance with design conditions and factors within the scope of the appended claims or their equivalents.

1. An electronic device comprising:
a first electrode part comprising a conductive material;
a second electrode part spaced apart from the first electrode part and including a conductive material;
an active layer disposed between the first electrode part and the second electrode part, including a spontaneously polarizable material, and formed to optionally have a first mode having a first electrical resistance and a second mode having a value smaller than the first electrical resistance; and
an electric field controller connected to the first electrode part and the second electrode part to apply an electric field.

2. The electronic device of claim 1, further comprising
a first connection electrode and a second connection electrode formed to be spaced apart from the first electrode part and the second electrode part on the active layer.

3. A method of controlling an electronic device which comprises a first electrode part including a conductive material, a second electrode part spaced apart from the first electrode part and including a conductive material, an active layer disposed between the first electrode part and the second electrode part, including a spontaneously polarizable material, and formed to optionally have a first mode having a first electrical resistance and a second mode having a value smaller than the first electrical resistance, and an electric field controller connected to the first electrode part and the second electrode part to apply an electric field, the method comprising:
optionally controlling a resistance value of the electronic device by controlling the selection of the first mode and the second mode of the active layer.

4. The method of claim 3, wherein
the electronic device further includes a first connection electrode and a second connection electrode formed to be spaced apart from the first electrode part and the second electrode part on the active layer, and
the flow of current between the first connection electrode and the second connection electrode is controlled.
